(19) United States
(12) Patent Application Publication
(10) Pub. No.: US 2009/0068494 A1
(43) Pub. Date: Mar. 12, 2009

(54) Metal Strip Product, Such as an Electrical Contact Spring, and the Manufacturing Thereof

(76) Inventors: Finn T. Petersen, Roskilde (DK); Thomas Christiansen, Frederikssund (DK); Rasmus B. Frandsen, Langa (DK); Marcel A.J. Somers, Billund (DK)

Correspondence Address: David M. Carter;Carter, DeLuca, Farrell & Schmidt, 445 Broad Hollow Road, Suite 225, Melville, NY, 11747, US

(21) Appl. No.: 11/920,453

(22) PCT Filed: May 24, 2006
(86) PCT No.: PCT/SE2006/000620

§ 371 Date: Nov. 15, 2007

Related U.S. Application Data
(60) Provisional application No. 60/687,102, filed on Jun. 3, 2005.

(30) Foreign Application Priority Data
May 31, 2005 (DK) PA 2005 00789

(51) Int. Cl. B32B 15/01; C23C 16/32; C23C 16/34; C25D 7/06

(52) U.S. Cl. 428/668; 427/255.394; 427/255.28; 427/249.2; 205/149

(57) ABSTRACT

A metal strip member (1) comprising a metal strip (2) having a thickness of less than 3 mm, and at least adjacent one side (3) consists of a substrate alloy with a chromium content of at least 10 wt %. The substrate alloy is on at least one side of the metal strip provided with a surface layer (4) of nickel, ruthenium, cobalt, palladium or an alloy thereof. Carbon and/or nitrogen atoms (5) are dissolved in the substrate alloy adjacent the surface layer providing compressive stresses, and essentially no carbides and/or nitrides are present in the substrate alloy. The invention also relates to resilient electrical contact spring member made of such a metal strip member and a method of manufacturing such a metal strip member.

The invention relates to a metal strip member according to the preamble of claim 1 and a method of manufacturing such a metal strip member.

Metal strip members are e.g. used as contact arms for electronic devices such as mobile phones, computers etc. The prior art discloses different solutions to the requirements to be met by such contact arms. These requirements are:
low contact resistance
good conductivity
good spring characteristics
high fatigue strength
high corrosion resistance

Alloys with a chromium content of at least 10%, e.g., stainless steel or nickel-based alloys have a superior corrosion resistance due to the presence of a passive chromium oxide layer on the surface. Furthermore, these materials have excellent spring properties, making them suitable as material for contact springs. However, the chromium oxide layer provides a high electrical resistance, whereby such materials per se are not suitable as contact materials.

For several years, resilient contact arms made of stainless steel and coated with a material such as nickel, copper or tin have been proposed.

U.S. Pat. No. 3,837,818 discloses a strip formed contact strip member made of copper sandwiched between two layers of stainless steel in order to obtain good spring characteristics and good electrical conductivity. A layer of gold is arranged on the stainless steel to obtain low contact resistance.

EP 604 856 B1 discloses a strip formed contact strip member made of a stainless steel which is coated with nickel, and where a noble metal, tin or a tin alloy is plated on the nickel coating.

The problem with this prior art is that the fatigue strength under certain circumstances can be insufficient. When the metal strip member is used as contact material and is repeatedly bended, at least one side of the strip member is subjected to dynamic tensile stresses. These tensile stresses may result in fatigue failure after a period of time. Fatigue failure of material often occurs if micro cracks are present, and the material is subject to dynamic loads comprising tensile stresses.

WO 2004/007789 discloses a method of case-hardening a stainless steel article by means of gas including carbon and/or nitrogen, whereby carbon and/or nitrogen atoms diffuse through the surface of the article, the method including applying a top layer of Ni, Ru, Co or Pd on the activated surface to prevent repassivation. The case-hardening is carried out below a temperature at which nitrides or carbides are produced.

The object of the invention is not limited to contact arms for electronic devices but also other strip shaped articles which are subjected to dynamic tensile stresses, such as flapper valves or reed valves which are used in compressors, car suspension systems, etc.

The object of the invention is to provide a metal strip member with improved properties compared to the prior art and a method of manufacturing such a metal strip member.

The metal strip member according to the invention comprises a metal strip having a thickness of less than 3 mm, and at least adjacent one side consists of a substrate alloy with a chromium content of at least 10 wt %, and where the substrate alloy on at least one side of the metal strip is provided with a surface layer of nickel, ruthenium, cobalt, palladium or an alloy thereof, and is characterised in that carbon and/or nitrogen atoms are dissolved in the substrate alloy adjacent the surface layer providing compressive stresses, and that essentially no carbides and/or nitrides are present in the substrate alloy. The compressive stresses caused by the carbon atoms and/or nitrogen atoms which are dissolved in the substrate alloy adjacent the surface layer at least partly compensate for the bending stresses caused by bending the strip member. If carbon atoms and/or nitrogen atoms are dissolved in the substrate material without the creation of carbides or nitrides, the corrosion resistance can be maintained. Furthermore, carbides or nitrides are relatively brittle compared to the surrounding material and may, if they were present, reduce the so-called crack resistance which may promote fatigue failure.

According to an embodiment of the invention the substrate alloy is a stainless steel or a nickel base alloy. Stainless steel has iron as base material, whereas the nickel base alloy has nickel as base material. Besides, the chromium content, the nickel base alloy may comprise cobolt, aluminium and other alloy elements.

According to a preferred embodiment the metal strip is completely made of the substrate alloy.

According to an embodiment the substrate alloy is a precipitation hardening stainless steel, preferably a martensitic precipitation hardening stainless steel.

According to the invention both sides of the metal strip member can be provided with said surface layer. This is suitable when it is desired that both sides of the metal strip member, while being used, will make contact to other contact members, and/or if the metal strip member is subject to tensile stresses on both sides, while being used.

According to an embodiment the metal strip is cold-rolled and has a minimum tensile strength of 1000 MPa. Cold-rolling of metal sheets improves the mechanical strength but induces internal tensile stresses in the surface. By dissolving carbon and/or nitrogen atoms in the material adjacent the surface, compressive stresses can be provided in order to improve the fatigue strength.

The average thickness of the surface layer can be less than 2 μm, preferably less than 0.3 μm. Test results have shown that it is possible to case-harden through surface layers of these thicknesses.

The metal strip member can be used as a resilient, electrical contact strip member.

The metal strip member can also be used in a so-called flapper valve or reed valve, in which the valve member consists of a flexible strip member which is covering the valve opening and is fastened at one end only. Such valves are typically used in compressors and are subjected to heavy dynamic tensile stresses.

The invention further relates to a method of manufacturing a metal strip member, which method comprising the following steps:
providing a metal strip that has a thickness of less than 3 mm and at least adjacent one side consists of a substrate alloy with a chromium content of at least 10 wt %,
removing the oxide layer on the substrate alloy on at least one side of the metal strip,
coating said side of the metal strip with a surface layer of nickel, ruthenium, cobalt, palladium, or an alloy thereof,
case-hardening the substrate alloy through said surface layer by means of gas including carbon and/or nitrogen, whereby carbon and/or nitrogen atoms diffuse through the surface layer, such that carbon and/or nitrogen atoms are dissolved in the substrate alloy adjacent the surface layer and compressive stresses are developed in the substrate alloy adjacent the surface layer, which case-hardening is carried out below a temperature at which carbides and/or nitrides are produced.

According to an embodiment of the invention the case-hardening is a nitriding process, which is carried out with a nitrogen-containing gas, such as NH₃, below a temperature at which nitrides are produced, preferably below approximately 450° C.

Alternatively, the case-hardening is carburizing with a carbon-containing gas, such CO, below a temperature at which carbides are produced, preferably below approximately 550° C., more preferably below approximately 510° C.

According to an embodiment metal strip is completely made of the substrate alloy, and wherein the substrate alloy is a precipitation hardening stainless steel, preferably a martensitic precipitation hardening stainless steel. During the case-hardening at the elevated temperature the substrate alloy precipitation hardens without forming nitrides or carbides. In this way too large differences between the hardness at the surface and the hardness at the central parts of the substrate alloy can be avoided.

The surface layer can be applied by a chemical or electrolytic plating process.

Alternatively, the surface layer is applied by physical vapour deposition, e.g. electron beam evaporation.

In a preferred embodiment of the method according to the invention a metal strip band is, in a continuous roll-to-roll process, passed through an electron beam evaporation chamber, in which beam evaporation chamber the surface layer is applied, where after metal strips are cut from the metal strip band.

Before entering the beam evaporation chamber the metal strip band can be passed through an etch chamber, in which ion-assisted etching takes place in order to remove the oxide layer.

In an embodiment of the method according to the invention the metal strip is bended to a desired shape before the case-hardening.

The invention will be explained below with reference to the drawing, in which

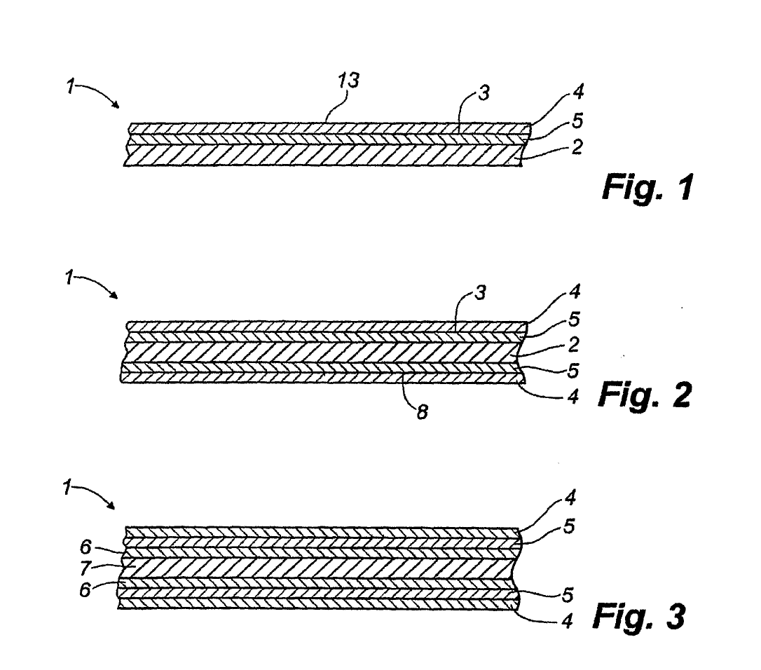

FIG. 1 discloses a part of a metal strip member according to a first embodiment of the invention,

FIG. 2 a part of a metal strip member according to a second embodiment of the invention,

FIG. 3 a part of a metal strip member according to a third embodiment of the invention,

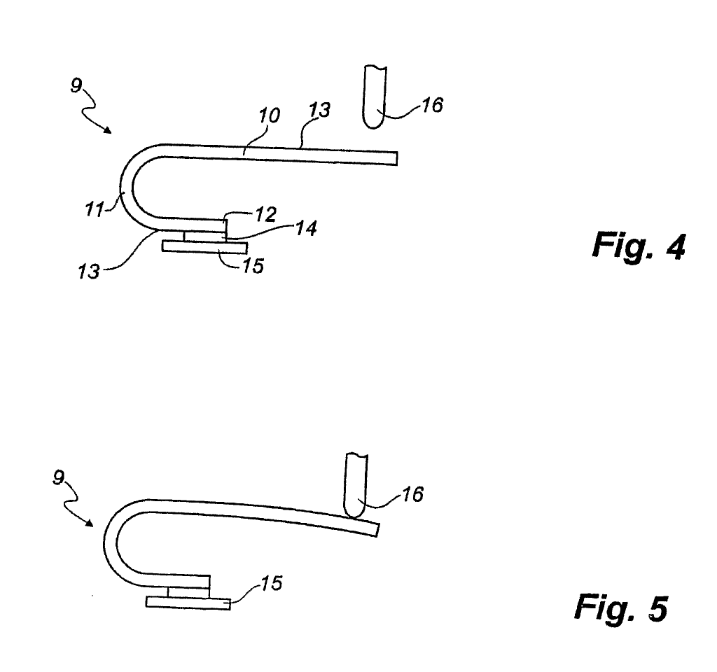

FIG. 4 a resilient electrical contact spring member made from a metal strip according to the invention in an open position, and

FIG. 5 the contact spring member according to FIG. 4 in a closed position.

The metal strip member 1 according to FIG. 1 comprises a metal strip 2 with a thickness of 3 mm and made of austenitic stainless steel AISI 304. The metal strip is on a first side 3 covered with a nickel layer 4 with an average thickness of 0.2 μm. This nickel layer has a relatively low contact resistance compared to stainless steel and provides a contact face 13. The nickel layer was plated in a Wood's nickel bath after a depassivation of the stainless steel surface in a solution of 100 ml 15% w/w hydrochloric acid+1 ml 35% hydrogen peroxide for 15 seconds. The stainless steel comprises an “S-phase” layer 5 adjacent the nickel layer 4. S-phase is also called “expanded austenite” and consists of nitrogen atoms (or carbon atoms) dissolved in the stainless steel. This expanded austenite provides compressive stresses in the material. The S-phase was obtained by case hardening the stainless steel through the nickel layer in a furnace flushed with pure NH₃ for 17 hours and 30 minutes at 429° C. When the case hardening is carried out at this temperature no chromium nitrides are formed. Thus, the free chromium content and thereby the corrosion resistance is maintained. Furthermore, the risk of fatigue failure is reduced due to the lack of presence of brittle chromium nitride.

The metal strip member 1 according to FIG. 2 corresponds to the metal strip member according to FIG. 1, but is provided with a nickel layer 4 and an S-phase layer 5 on both sides 3, 8 of the stainless steel strip 2. Therefore, the metal strip member according to FIG. 2 has a contact face on both sides.

The metal strip member 1 according to FIGS. 1 and 2 comprises a metal strip 2 which is completely made of stainless steel and a nickel layer on one or both sides, respectively. The metal strip member 1 according to FIG. 3 comprises a metal strip which is made of a sandwich material. A central core layer 7 of copper is sandwiched between two layers 6 of stainless steel. This embodiment ensures that a good electrical conductivity and good spring properties are obtained simultaneously.

FIG. 4 discloses a resilient electrical contact spring member 9 made of a metal strip member according to FIG. 1. The metal strip member 9 is bent through 180° such that it comprises an upper straight part 10, a curved part 11 and a lower straight part 12. The contact face 13 comprising a nickel layer (not shown) and an underlying S-phase layer (not shown) points upwards at the upper straight part 10 of the contact spring member 9 and downwards at the lower straight part 12 of the contact spring member 9. The lower straight part 9 is soldered to a solder point 15 by means of a solder joint 14. A movable second contact member 16 is arranged above the contact face 13 of the upper straight part 10. The second contact member 16 is movable in the direction of the arrow A to the upper straight part 10 in order to close the contact. FIG. 5 discloses the contact in a closed position, in which the solder point 15 and the second contact member 16 are electrically connected. As shown in FIG. 5, the second contact member has flexed the resilient contact spring member 9, whereby the side with the contact face 13 is stretched. If no initial internal stresses were present in the contact spring 9, this stretching would cause tensile stresses on the outer side of the contact spring 9. The initial compressive stresses caused by the S-phase prevent or at least reduce the occurrence of tensile stresses caused by the stretching. Therefore, the risk of fatigue failure is reduced significantly, even though the contact spring member is flexed up to hundred thousand times or more.

The embodiment disclosed in FIGS. 4 and 5 has a contact face 13 on one side only. However, if both sides were subject to stretching while being used, they could be provided with a nickel layer and an underlying S-phase layer.

In the disclosed embodiments AISI 304 stainless steel is used as substrate alloy. Other austenitic stainless steel types such as AISI 316 can also be used.

Further, Duplex stainless steel AISI 329 consisting of ferrite and austenite can be used. Tests have shown that when nitriding at 400° C., ferrite is transformed into austenite (and S-phase) in the case-hardened zone.

Preliminary tests have shown that also AISI 420, which is a martensitic stainless steel, and AISI 17-4 PH, which is a martensitic precipitation hardening stainless steel, can be used, as the martensite is transformed into austenite (and S-phase) in the case-hardened zone.

When a precipitation hardening stainless steel is used as substrate alloy, a precipitation hardening of the substrate alloy takes place during the case-hardening. Thereby the disadvantages of having a hard surface and a relatively soft inner core can be reduced. A suitable precipitation hardenable martensitic stainless steel is known from U.S. Pat. No. 5,512,237.

Also, nickel-base alloys such as Inconel alloys can be used. As with stainless steel, nitrogen and/or carbon atoms can diffuse into the nickel-base alloy and form the metastable S-phase (solid solution hardening).

Nickel is a very suitable material for the surface layer due to its relatively low contact resistance and its high corrosion resistance. Nickel is catalytic to the decomposition of nitrogen and carbon containing gasses such as NH₃, CO and CₓHₓ. If the nickel layer is sufficiently thin, the nitrogen and carbon atoms can diffuse through it and into the underlying substrate alloy. In some cases, other materials than nickel might be chosen for the surface layer. Ruthenium, cobalt and palladium are also corrosion resistant, catalytic to the decomposition of nitrogen and carbon containing gasses and permeable to nitrogen and carbon atoms. Naturally, alloys of these metals can be used instead of a single metal. The surface layer should be sufficiently thick to prevent passivation of the underlying substrate alloy and sufficiently thin to allow nitrogen and/or carbon atoms to diffuse through the surface layer.

The metal strip member according to the invention is case-hardened, whereby nitrogen and/or carbon atoms are dissolved in the substrate alloy adjacent the surface layer. The case-hardening is carried out by arranging the metal strip member in a gas containing nitrogen and/or carbon atoms at an elevated temperature. Thermo-chemical surface treatments of steel by means of carbon or nitrogen carrying gases are well-known processes, called case-hardening, carburization or nitriding. Generally, these processes are carried out at temperatures at which carbides or nitrides are formed, whereby the hardness is improved. According to the invention the case-hardening is carried out below these temperatures. If the temperature is kept below 450° C., chromium nitrides will not be formed, and if the temperature is kept below 550° C., chromium carbides will not be formed. Also, nitro-carburization which involves a gas carrying both carbon and nitrogen can be used with this invention. By nitro-carburization, both nitrogen and carbon atoms diffuse into the material. In this case, the temperature must be kept below 450° C. in order to avoid the formation of chromium nitrides.

The surface layer of nickel, ruthenium, cobalt, palladium or an alloy thereof can be applied in any known method such as electro-plating, electroless plating physical vapour deposition or chemical vapour deposition.

In the disclosed embodiments the surface layer completely covers one or both sides of the metal strip. However, the invention is not restricted in this manner. Thus, the surface layer may cover only parts of the metal strip. A partial covering of the metal strip with a surface layer can be obtained by masking off those areas of the surface which should not be covered by the surface layer. Alternatively, ink-jet printing methods where a dual nozzle performs 2-component metallization can be used.

The metal strip member according to the invention is suitable as a contact material due to the relatively low contact resistance of the surface layer which can be of nickel, ruthenium, cobalt, palladium or an alloy thereof. However, in order to reduce the contact resistance further, a top layer can be applied on the surface layer after the case-hardening. A surface layer of nickel can e.g. be coated with a layer of silver or gold. This top layer does not necessarily have to cover the surface completely but only an area in which a particularly low contact resistance is desired.

The metal strip member according to the invention is suitable as a contact material. The invention, however, is not restricted to such a use. Other applications where a high fatigue strength and high corrosion resistance are desired may benefit by the metal strip member according to the invention. Such applications can be flapper valves used in compressors etc.

### EXAMPLE 1

A cold rolled sheet of stainless steel AISI 301 with a thickness of 70 μm (=0.07 mm) was coated with a 100 nm (=0.1 μm) thick nickel layer on one side. The sheet was nitrided at 420° C. for 17 hours in 60% ammonia. After this treatment the sheet curved due to volume expansion of the nitrided side of the sheet. This demonstrates that internal compressive stresses occur by the nitriding if the sheet is sufficiently thick to avoid bending.

### REFERENCE NUMERALS

1 metal strip member
2 metal strip
3 first side of metal strip
4 surface layer
5 S-phase (dissolved carbon and/or nitrogen atoms)
6 layer of substrate alloy
7 centre layer
8 second side of metal strip
9 bended contact strip member
10 upper part of contact strip member
11 curved part of contact metal member
12 lower part of contact metal member
13 contact face of contact metal member
14 solder joint
15 solder point
16 second contact member

1. A metal strip member (1) comprising a metal strip (2) which has a thickness of less than 3 mm and at least adjacent one side (3) includes a substrate alloy with a chromium content of at least 10 wt %, and where the substrate alloy on at least one side of the metal strip is provided with a surface layer (4) of nickel, ruthenium, cobalt, palladium or an alloy thereof, wherein carbon and/or nitrogen atoms (5) are dissolved in the substrate alloy adjacent the surface layer providing compressive stresses, and that essentially no carbides and/or nitrides are present in the substrate alloy.

2. A metal strip member according to claim 1, where the substrate alloy is stainless steel or a nickel base alloy.

3. A metal strip member according to claim 1, wherein the metal strip (2) is completely made of the substrate alloy.

4. A metal strip member according to claim 3, wherein the substrate alloy is a precipitation hardening stainless steel.

5. A metal strip member according to claim 1, wherein both sides (3, 8) are provided with said surface layer (4).

6. A metal strip member according to claim 1, wherein the metal strip is cold rolled and has a minimum tensile strength of 1000 MPa.

7. A metal strip member according to claim 1, wherein the average thickness of the surface layer (4) is less than 2 μm.

8. A resilient electrical contact spring member (9) made from a metal strip member according to claim 1.

9. A method of manufacturing a metal strip member, the method comprising the following steps:
providing a metal strip that has a thickness of less than 3 mm and at least adjacent one side includes a substrate alloy with a chromium content of at least 10 wt %;
removing the oxide layer on the substrate alloy on at least one side of the metal strip,
coating said side of the metal strip with a surface layer of nickel, ruthenium, cobalt, palladium or an alloy thereof,
case-hardening the substrate alloy through said surface layer by means of gas including carbon and/or nitrogen, whereby carbon and/or nitrogen atoms diffuse through the surface layer, such that carbon and/or nitrogen atoms are dissolved in the substrate alloy adjacent the surface layer and compressive stresses are developed in the substrate alloy adjacent the surface layer, which case-hardening is carried out below a temperature at which carbides and/or nitrides are produced.

10. A method according to claim 9, wherein the case-hardening is a nitriding process which is carried out with a nitrogen-containing gas below a temperature at which nitrides are produced.

11. A method according to claim 9, wherein the case-hardening is carburizing with a carbon-containing gas below a temperature at which carbides are produced.

12. A method according to claim 9, wherein the metal strip (2) is completely made of the substrate alloy, and wherein the substrate alloy is a precipitation hardening stainless steel.

13. A method according to claim 9, wherein the surface layer is applied by a chemical or electrolytic plating process.

14. A method according to claim 9, wherein the surface layer is applied by physical vapour deposition.

15. A method according to claim 14, wherein a metal strip band in a continuous roll-to-roll process is passed through an electron beam evaporation chamber, in which beam evaporation chamber the surface layer is applied, where after metal strips are cut from the metal strip band.

16. A method according to claim 15, wherein the metal strip band before entering the beam evaporation chamber is passed through an etch chamber, in which ion-assisted etching takes place in order to remove the oxide layer.

17. A method according to claim 9, where the metal strip is bended to a desired shape before the case-hardening.

18. A metal strip according to claim 4, wherein the precipitation hardening stainless steel is a martensitic precipitation hardening stainless steel.

19. A metal strip according to claim 7, wherein the surface layer has a thickness of less than 0.3 μm.

20. A method according to claim 10, wherein the step of case-hardening includes a nitriding process carried out with NH₃.

21. A method according to claim 10, wherein the step of case-hardening includes a nitriding process carried out below about 450° C.

22. A method according to claim 11, wherein the step of case-hardening includes carburizing the substrate alloy with CO.

23. A method according to claim 11, wherein the step of case-hardening includes carburizing the substrate alloy below a temperature of about 550° C.

24. A method according to claim 11, wherein the step of case-hardening includes carburizing the substrate alloy below at temperature of about 510° C.

25. A method according to claim 12, wherein the step of providing a metal strip includes providing a metal strip wherein the substrate alloy is a martensitic precipitation hardening stainless steel.

26. A method according to claim 14, wherein the step of coating the first side with a surface layer includes coating the first side with a surface layer by electron beam evaporation.
